(19) United States
(12) Patent Application Publication
(10) Pub. No.: US 2024/0339392 A1
(43) Pub. Date: Oct. 10, 2024

(54) ELECTRONIC DEVICE

(71) Applicant: InnoLux Corporation, Miao-Li County (TW)

(72) Inventors: Chih-Hao CHANG, Miao-Li County (TW); Te-Hsun LIN, Miao-Li County (TW); Wen-Hsiang LIAO, Miao-Li County (TW)

(21) Appl. No.: 18/599,624

(22) Filed: Mar. 8, 2024

Related U.S. Application Data
(60) Provisional application No. 63/494,477, filed on Apr. 6, 2023.

(30) Foreign Application Priority Data
Dec. 13, 2023 (CN) 202311713701.5

(51) Int. Cl. H01L 23/498; H01L 23/00

(52) U.S. Cl. CPC H01L 23/49838; H01L 23/49827; H01L 24/20; H01L 24/16; H01L 24/19; H01L 2224/16227; H01L 2224/19; H01L 2224/211

(57) ABSTRACT

An electronic device includes a circuit structure including: a first insulation layer including a first opening; a second insulation layer disposed in the first opening and including a second opening; a conductive connection layer disposed in the second opening; and a first conductive layer and a second conductive layer respectively disposed on a surface and another surface of the first insulation layer. The first and the second conductive layer are electrically connected through the conductive connection layer, and the Young's modulus of the second insulation layer is less than the Young's modulus of the first insulation layer. In a cross-section of the electronic device, a center of the second opening and an outer surface of the second insulation layer are separated by a first distance X1, and a maximum width W of the second opening and the first distance X1 conform to the following formula:

$$1.5 W ≦ {X}_{1} < 3 W .$$

### CROSS REFERENCE TO RELATED APPLICATIONS

This application claims priority of China Patent Application No. 202311713701.5, filed on Dec. 13, 2023, which claims the benefit of U.S. Provisional Application No. 63/494,477, filed on Apr. 6, 2023, the entirety of which is incorporated by reference herein.

### BACKGROUND OF THE INVENTION

### Field of the Invention

The present invention relates to an electronic device, and, in particular, to an electronic device including a circuit structure.

### Description of the Related Art

An electronic device includes electronic elements and a circuit structure. The circuit structure includes conductive layers and insulation layers. In some manufacturing processes, the electronic device is subjected to a heating process. The conductive layers and the insulation layers in the circuit structure are susceptible to cracking, damage or delamination of the insulation layer due to large differences between the thermal expansion coefficients of the conductive layers and the insulation layers. Therefore, the reliability of the electronic device will be reduced.

### BRIEF SUMMARY OF THE INVENTION

In order to meet users' requirements for the reliability of electronic devices, the present disclosure provides an electronic device including a new circuit structure.

An embodiment of the present invention provides an electronic device including a circuit structure having a first side and a second side that are opposite to each other, a chip disposed on the first side of the circuit structure, a pad disposed on the second side, and a solder structure contacting the pad. The circuit structure includes: a first insulation layer having a first opening and a surface and another surface that are opposite to each other; a second insulation layer disposed in the first opening and has a second opening; a conductive connection layer disposed in the second opening; and a first conductive layer and a second conductive layer respectively disposed on the surface and the other surface of the first insulation layer. The first conductive layer and the second conductive layer are electrically connected through the conductive connection layer, and the Young's modulus of the second insulation layer is less than the Young's modulus of the first insulation layer. In a cross-section of the electronic device, the center of the second opening and the outer surface of the second insulation layer are separated by a first distance X₁, and the maximum width W of the second opening and the first distance X₁ conform to the following formula:

$$1.5 W ≦ {X}_{1} < 3 W .$$

### BRIEF DESCRIPTION OF THE DRAWINGS

In order to make the above purposes, features and advantages of the present disclosure more obvious and easy to understand, the following specific embodiments of the present disclosure are described in detail in conjunction with the accompanying drawings, wherein:

FIG. 1A is a schematic cross-sectional view of an electronic device according to an embodiment of the present disclosure;

FIG. 1B is a schematic top view of a first insulation layer according to an embodiment of the present disclosure;

FIG. 2 is a schematic cross-sectional view of an electronic device according to another embodiment of the present disclosure;

FIG. 3A is a schematic cross-sectional view of an electronic device according to another embodiment of the present disclosure;

FIG. 3B is a schematic top view of a first insulation layer according to an embodiment of the present disclosure;

FIGS. 4A to 4D are schematic cross-sectional views of circuit structures, pads, and solder structures according to some embodiments of the present disclosure;

FIGS. 5A to 5G are cross-sectional views of an electronic device during preparation of the electronic device according to some embodiments of the present disclosure;

FIG. 5H is an enlarged view of an area A in FIG. 5G;

FIGS. 6A to 6D are cross-sectional views of an electronic device during the preparation of the electronic device according to other embodiments of the present disclosure; and

FIG. 7A and FIG. 7B are cross-sectional views of an electronic device during the preparation of the electronic device according to other embodiments of the present disclosure.

### DETAILED DESCRIPTION OF THE INVENTION

The following description recites various embodiments of the present disclosure to introduce a basic concepts of the present disclosure, and the following description is not intended to limit the content of the present disclosure. The actual scope of the present disclosure should be defined according to claims. Reference will now be made in detail to exemplary embodiments of the present disclosure, examples of which are illustrated in the accompanying drawings. Whenever possible, the same reference numbers are used in the drawings and descriptions to refer to the same or similar parts.

The directional terms mentioned in the disclosure, such as “up”, “down”, “front”, “back”, “left”, “right” only refer to the directions of the accompanying drawings. Therefore, the directional terms used herein are illustrative and not intended to limit the disclosure. In the drawings, each drawing illustrates general features of methods, structures, and/or materials used in specific embodiments. However, these drawings should not be interpreted as defining or limiting the scope or properties encompassed by these embodiments. For example, the relative sizes, thicknesses, and locations of various layers, regions, and/or structures may be reduced or exaggerated for clarity.

In the present disclosure, descriptions of a structure (or layer, component or substrate) being on/above another structure (or layer, component or substrate) may mean that the two structures are adjacent and directly connected, or that the two structures are adjacent and indirectly connected. Indirect connection means that there is at least one intermediate structure (or intermediate layer, intermediate component, intermediate substrate, intermediate spacer) between two structures. A lower surface of the structure is adjacent to or directly connected to an upper surface of the intermediate structure, and an upper surface of the other structure is adjacent to or directly connected to a lower surface of the intermediate structure. The intermediate structure may be a single-layer or multi-layer physical structure or a non-physical structure without limitation. In the disclosure, when a structure is disposed “on” another structure, it may mean that the structure is “directly” on the other structure, or that the structure is “indirectly” on the other structure, i.e. there is at least one structure is between the structure and the other structure.

The present disclosure may be understood by referring to the following detailed description and combined with the accompanying drawings. It should be noted that in order to make it easy for readers to understand and for the simplicity of the drawings, many of the drawings in the present disclosure only depict a portion of an electronic devices, and certain elements in the drawings are not drawn to actual scale. In addition, the number and size of elements in the drawings are only for illustration and are not intended to limit the scope of the present disclosure.

Throughout the disclosure and the appended claims, some terms are used to refer to specific elements. Those skilled in the art will understand that electronic device manufacturers may refer to the same element by different names. The disclosure is not intended to differentiate between elements that have the same function but have different names.

In the following description and claims, the words “include” and “comprise” are open-ended words, so they should be interpreted as meaning “including but not limited to . . . ”.

In addition, relative terms, such as “below” or “bottom” and “above” or “top”, may be used in the embodiments to describe the relative relationship of one element to another element in the drawings. It will be understood that if the device is turned upside down in the drawing, elements described as “below” would be elements described as “above”.

In some embodiments of the present disclosure, unless otherwise defined, terms related to joining and connecting, such as “connection”, “interconnection”, etc., may mean that two structures are in direct contact, or may also mean that the two structures are not in direct contact (indirect contact) and other structures are between the two structures. The terms related to joining and connecting may also include the situation where both structures are movable or both structures are fixed. In addition, the term “electrical connection” includes the transfer of energy between two structures by direct or indirect electrical connection, or the transfer of energy between two separate structures by mutual induction.

It should be understood that when an element or layer is referred to as being “on” or “connected to” another element or layer, it may be directly on the other element or layer, or directly connected to the other element or layer, or there is an intermediate element or layer between them (indirect case). In contrast, when an element is referred to as being “directly on” or “directly connected to” another element or layer, there are no intermediate elements or layers between them. It should be understood that when an element or layer is referred to as being “connected to” another element or layer, the element may be electrically connected to the other element or layer directly, or the element may be electrically connected to the other element or layer via other conductive elements.

In the disclosure, the terms “about”, “equal to”, “equal” or “the same”, “substantially” or “approximately” usually indicates a value of a given value or range that varies within 20%, or a value of a given value or range that varies within 10%, within 5%, or within 3%, or within 2%, or within 1%, or within 0.5%.

Furthermore, any two numerical values or directions used for comparison may have certain errors. If the first value is equal to the second value, it implies that there may be an error of about 10% between the first value and the second value. If the first direction is perpendicular or “substantially” perpendicular to the second direction, the angle between the first direction and the second direction may be between 80 degrees and 100 degrees. If the first direction is parallel or “substantially” parallel to the second direction, the angle between the first direction and the second direction may be between 0 degrees and 10 degrees.

Ordinal numbers used in the specification and claims, such as “first”, “second”, etc., are used to modify elements. The ordinal numbers do not imply or represent numbers of the element (or elements). The ordinal numbers do not represent the order of one element over another or the order of manufacturing method. The ordinal numbers are only used to clearly distinguish two elements having the same name. The claims and the specification may not use the same terms. Therefore, the first element in the specification may be the second component in the claim.

In the present disclosure, the terms “a given range is a first value to a second value” and “a given range falls within the range of a first value to a second value” indicate that the given range includes the first value, the second value, and other values between them.

It should be understood that according to the embodiments of the present disclosure, the depth, thickness, width or height of each element, or the space of the elements or the distance between them may be measured using an optical microscope (OM), a scanning electron microscope (SEM), a film thickness profile measuring gauge (α-step), an elliptical thickness gauge, or other suitable measurement methods. According to some embodiments, a scanning electron microscope may be used to obtain a cross-sectional structural image including the elements to be measured, and to measure the depth, thickness, width or height of each element, or the space or distance between elements.

The electronic device of the present disclosure may include electronic elements. Electronic elements may include passive elements, active elements, or a combination of the foregoing, such as capacitors, resistors, inductors, varactor diodes, variable capacitors, filters, diodes, transistors, sensors, microelectromechanical system (MEMS) elements, liquid crystal chips, etc., but are not limited thereto. The diodes may include light emitting diodes or non-light emitting diodes. The diodes may include P-N junction diodes, PIN diodes or constant current diodes. The light emitting diodes may include, for example, organic light emitting diodes (OLEDs), submillimeter light emitting diodes (mini LEDs), micro light emitting diodes (micro LEDs), quantum dot light emitting diodes (quantum dot LEDs), fluorescence diodes, phosphor diodes or other suitable materials, or any combination of the foregoing, but are not limited thereto. The sensors may include, for example, capacitive sensors, optical sensors, electromagnetic sensors, fingerprint sensors (FPS), touch sensors, antennas, or pen sensors, etc., but are not limited to thereto. Electronic elements may include dies or LED dies, which may be a die made of silicon (Si), gallium arsenide (GaAs), gallium nitride (GaN), silicon carbide (SiC), sapphire or a glass substrate, but is not limited thereto. In another embodiment, the above-mentioned chips may include a semiconductor packaging element, such as a ball grid array (BGA) packaging element, a chip size package (CSP) element, a flip chip or a 2.5D/3-dimensional (2.5D/3D) semiconductor packaging element, but is not limited thereto. In another embodiment, the chip may be any flip-chip bonding element, such as integrated circuits (ICs), transistors, controlled silicon rectifiers, valves, thin film transistors, capacitors, inductors, variable capacitors, filters, resistors, diodes, microelectromechanical system (MEMS) elements, liquid crystal chips, etc., but are not limited thereto. In addition, the chip may include, for example, a diode or a semiconductor chip, but is not limited thereto. The chip may be a known good die (KGD), which may include various electronic elements, such as (but not limited to) wires, transistors, circuit boards, etc. Adjacent chips may have different functions, such as integrated circuits, RFICs, and D-RAMs, but are not limited thereto.

Reference will now be made in detail to the exemplary embodiments of the present disclosure, examples of which are illustrated in the accompanying drawings. Whenever possible, the same reference numbers are used in the drawings and descriptions to refer to the same or similar parts. The electronic device may include an imaging device, a laminating device, a display device, a backlight device, an antenna device, a splicing device, a touch electronic device (touch display), a curved electronic device (curved display) or a non-rectangular electronic device (free shape display), but is not limited thereto. The electronic device may include, for example, liquid crystals, light emitting diodes, fluorescences, phosphors, other suitable display medias, or any combination of the foregoing, but are not limited thereto. The display device may be a non-self-luminous display device or a self-luminous display device. The antenna device may be a liquid crystal type antenna device or a non-liquid crystal type antenna device. Sensing device may be a sensing device that senses capacitance, light, heat energy or ultrasonic waves, but is not limited thereto. The splicing device may be, for example, a display splicing device or an antenna splicing device, but is not limited thereto. The electronic device described in the present disclosure may be applied to power modules, semiconductor packaging devices, display devices, light emitting devices, backlight devices, antenna devices, sensing devices or splicing devices, but is not limited thereto. The electronic device may be a bendable or flexible electronic device. The shape of the electronic device may be a rectangular shape, a circular shape, a polygonal shape, a shape with curved edges, or other suitable shapes. It should be noted that the features in various different embodiments may be substituted, rearranged or combined to complete other embodiments without departing from the spirit of the present disclosure. Features in different embodiments may be combined in any way as long as they do not violate the spirit of the invention or conflict with each other.

Unless otherwise defined, all terms (including technical and scientific terms) used herein have the same meaning as commonly understood by a person skilled in the art to which the disclosure pertains. It will be further understood that terms, such as those defined in commonly used dictionaries, should be interpreted as having a meaning consistent with the relevant technology and the context or background of this disclosure and will not be interpreted in an idealized or overly formal sense unless expressly so defined herein. An aspect of the present disclosure is to provide an electronic device including a novel circuit structure.

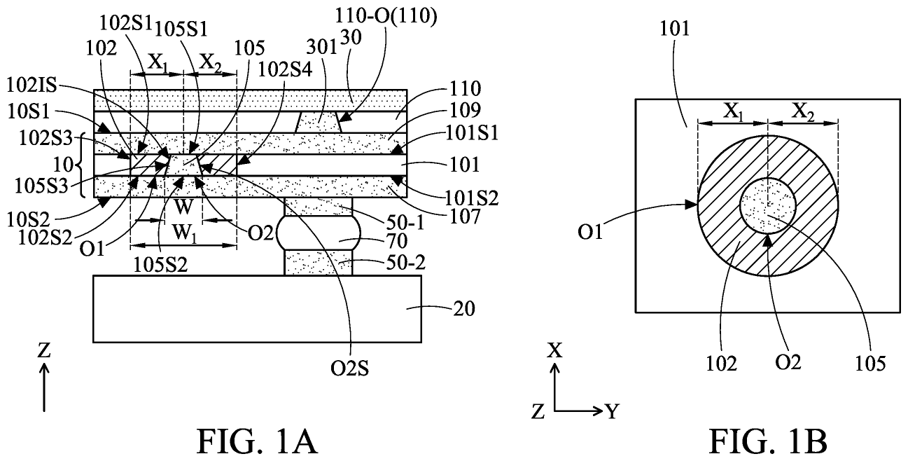

FIG. 1A is a schematic cross-sectional view of an electronic device according to an embodiment of the present disclosure. As shown in FIG. 1A, an electronic device according to an embodiment of the present disclosure may include a circuit structure 10 having a first side 10S1 and a second side 10S2 that are opposite to each other, a chip 30 disposed on the first side 10S1 of the circuit structure 10, a pad 50-1 disposed on the second side 10S2 of the circuit structure 10, and a solder structure 70 contacting the pad 50-1. The circuit structure 10 includes a first insulation layer 101, a second insulation layer 102, a conductive connection layer 105, a first conductive layer 107 and a second conductive layer 109. The first insulation layer 101 includes a first opening O1 and a surface 101S2 and another surface 101S1 that are opposite to each other. The second insulation layer 102 is disposed in the first opening O1 and includes a second opening O2. The conductive connection layer 105 is disposed in the second opening O2. The first conductive layer 107 is disposed on the surface 101S2 of the first insulation layer 101, and the second conductive layer 109 is disposed on the other surface 101S1 of the first insulation layer 101. The first conductive layer 107 and the second conductive layer 109 are electrically connected to each other by the conductive connection layer 105. The Young's modulus of the second insulation layer 102 is smaller than the Young's modulus of the first insulation layer 101. In a cross-section of the electronic device, the second opening O2 has a maximum width W. The center of the second opening O2 and the outer surface of the second insulation layer 102 are separated by a first distance X₁. The maximum width W of the second opening O2 and the first distance X₁ conform to the following formula: 1.5 W≤X₁<3 W. In some embodiments, the maximum width W of the second opening O2 and the first distance X₁ may conform to the following formula: 1.7 W≤X₁≤2.8 W. In some embodiments, the maximum width W of the second opening O2 and the first distance X₁ may conform to the following formula: 2 W≤X₁≤2.5 W. Details of the maximum width W of the second opening O2 and the first distance X₁ are described below.

In some embodiments, the first insulation layer 101 of the circuit structure 10 may include a single-layer structure or a stacked structure including multiple layers. The first insulation layer 101 may include an insulation material having a Young's modulus that is greater than 10 Gpa. In some embodiments, the first insulation layer 101 may include nitrides, oxides, nitrogen oxides, perfluoroalkoxyalkanes (PFA), resins, Ajinomoto build-up film (ABF), polybenzoxazoles (PBO), other suitable materials, or any combination of the foregoing, but is not limited thereto. In some embodiments, the first insulation layer 101 may include organic materials, inorganic materials, or other suitable insulation materials, such as (but not limited to) epoxy resins, silicon nitrides (SiNx), silicon oxides (SiOx), or any combination of the foregoing. In some embodiments, the first insulation layer 101 may include a glass or polyimides.

In some embodiments, the first opening O1 of the first insulation layer 101 may penetrate the first insulation layer 101. In some embodiments, when viewed in a Z-axis direction, the first opening O1 may have a circular (as shown in FIG. 1B), square, rectangular, polygonal or irregular opening shape, but is not limited thereto.

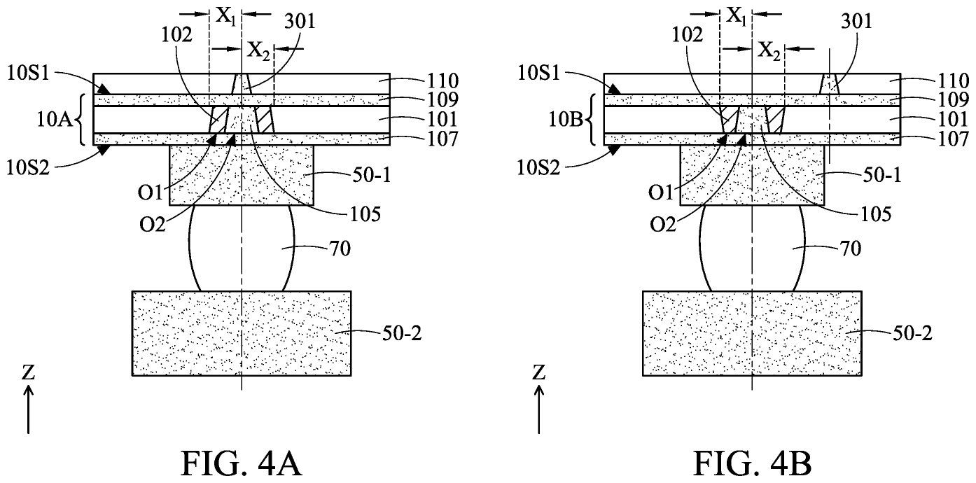

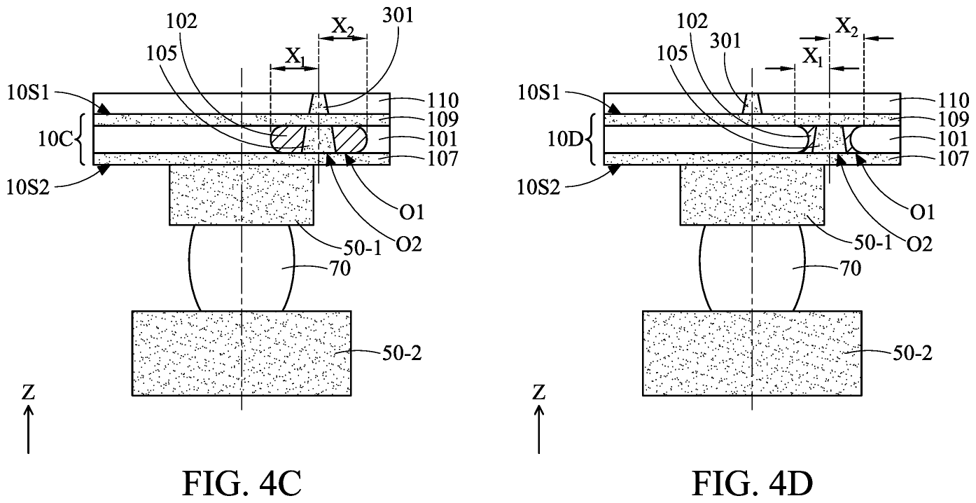

In some embodiments, in a cross-section of the first opening O1, the first opening O1 may have a regular trapezoidal cross-sectional shape, an inverted trapezoidal cross-sectional shape, a rectangular cross-sectional shape or other suitable cross-sectional shapes. In the cross-section of the first opening O1, the first opening O1 may include a cross-sectional shape having parallel opposite sides (as shown in FIG. 1A), non-parallel opposite sides (as shown in FIG. 4A or 4B), concave sides (as shown in FIG. 4D), or convex sides (as shown in FIG. 4C).

In some embodiments, the first opening O1 may have a maximum width (not shown, the maximum width of the first opening O1 is approximately equal to a maximum outline width W₁ of the second insulation layer 102 which will be mentioned later). “The maximum width of the first opening O1” is, for example, in a cross-section of the first opening O1, a maximum width of the first opening O1 measured in a direction perpendicular to the Z-axis direction. The cross-section of the first opening O1 may, for example, be a cross-section taken along a plane passing substantially through the center of the second opening O2. There may be a deviation in using a cross-section that substantially passes through the center of the second opening O2, i.e., for example, the cross-section may be taken along a plane which deviates slightly from the center of the second opening O2. If the second opening O2 has a circular opening shape, the center of the second opening O2 may be the center of the circular opening shape. If the opening shape of the second opening O2 is irregular, the center of the second opening O2 may be, for example, a point of intersection of two diagonal lines of a minimum rectangle outlining the second opening O2.

In some embodiments, the second insulation layer 102 may include a single-layer structure or a multi-layer structure. In some embodiments, the Young's modulus of the second insulation layer 102 may be between 0.1 Gpa and 10 Gpa (0.1 Gpa≤Young's modulus of the second insulation layer 102≤10 Gpa), but is not limited thereto. In some embodiments, the Young's modulus of the second insulation layer 102 may be between 0.1 Gpa and 8 Gpa (0.1 Gpa≤Young's modulus of the second insulation layer 102≤8 Gpa). In some embodiments, the Young's modulus of the second insulation layer 102 may be between 0.5 Gpa and 7 Gpa (0.5 Gpa≤Young's modulus of the second insulation layer 102≤7 Gpa). In some embodiments, the Young's modulus of the second insulation layer 102 may be between 1 Gpa and 6 Gpa (1 Gpa≤Young's modulus of the second insulation layer 102≤6 Gpa). In some embodiments, the ratio of the Young's modulus of the first insulation layer 101 to the Young's modulus of the second insulation layer 102 may be greater than 1, for example, greater than 1 and less than or equal to 10, or greater than 1 and less than or equal to 8, or greater than 1 and less than or equal to 6, or greater than 1 and less than or equal to 4, but not limited thereto. In some embodiments, the second insulation layer 102 may include elastomeric polymers. In some embodiments, the second insulation layer 102 may include photosensitive polyimides (PSPI), polyethylenes (PE), polyethylene terephthalates (PET), polycarbonates (PC), polytetrafluoroethylenes (PTFE), polystyrenes (PS), acrylonitrile butadiene styrenes (ABS), and other suitable materials, or any combination of the foregoing, but not limited thereto. The materials of the first insulation layer 101 and the second insulation layer 102 are different.

In some embodiments, the second insulation layer 102 is disposed in the first opening O1 and may include a surface 102S2 and another surface 102S1 that are opposite to each other. In some embodiments, the surface 102S2 of the second insulation layer 102 may be substantially level with the surface 101S2 of the first insulation layer 101, and the other surface 102S1 of the second insulation layer 102 may be substantially level with the other surface 101S1 of the first insulation layer 101, but is not limited thereto. In some embodiments, the first insulation layer 101 may surround the outer surface of the second insulation layer 102, such as an outer surface 102S3 and/or an outer surface 102S4, where the outer surface 102S3 and the outer surface 102S4 are, for example, two opposite sides in a cross-section of the second insulation layer 102. The second insulation layer 102 has a maximum outline width W₁. Here, “the maximum outline width W₁ of the second insulation layer 102” refers to in a cross-section of the second insulation layer 102, a maximum outline width of the second insulation layer 102 measured in a direction perpendicular to the Z-axis direction. In some embodiments, the maximum outline width measured here is equal to a maximum distance between the two opposite outer surfaces 102S3 and/or 102S4 in cross-section of the second insulation layer 102. The cross-section of the second insulation layer 102 may be, for example, a cross section taken along a plane passing substantially through the center of the second opening O2. The definition of the center of the second opening O2 may be referred to above. There may be a deviation in using a cross-section that substantially passes through the center of the second opening O2, i.e., for example, the cross-section may be taken along a plane which deviates slightly from the center of the second opening O2. In some embodiments, the second insulation layer 102 may, for example, be in contact with the first insulation layer 101. In some embodiments, as shown in FIGS. 1A and 1B, when viewed in the Z-axis direction, an outline shape of the second insulation layer 102 is substantially the same as the opening shape of the first opening O1. The cross-sectional outline shape of the second insulation layer 102 are same as the opening shapes of the first openings O1 of the first insulation layer 101.

In some embodiments, the second opening O2 of the second insulation layer 102 has a maximum width W. Here, “the maximum width W of the second opening O2” is, for example, in the cross-section of the second opening O2, a maximum width of the second opening O2 measured in the direction perpendicular to the Z-axis direction. In some embodiments, when view in the Z-axis direction, the second opening O2 may have a circular, rectangular, polygonal or irregular opening shape, but is not limited thereto. If the opening shape of the second opening O2 is irregular, the center of the second opening O2 may be, for example, a point of intersection of two diagonal lines of a minimum rectangle outlining the second opening O2. In some embodiments, the opening shape of the second opening O2 may be the same as or different from the opening shape of the first opening O1. As shown in FIG. 1B, the first opening O1 and the second opening O2 may have the same (for example, circular) opening shapes, but are not limited thereto.

In some embodiments, the maximum width W of the second opening O2 of the second insulation layer 102 and the maximum outline width W₁ of the second insulation layer 102 conform to the following formula: 3 W<W₁<6 W, but are not limited thereto. In some embodiments, the maximum width W of the second opening O2 of the second insulation layer 102 and the maximum outline width W₁ of the second insulation layer 102 conform to the following formula: 3.5 W≤W₁≤5.5 W or 4 W<W₁≤5 W, but are not limited thereto.

In some embodiments, in the cross-section of the second opening O2, the second opening O2 may have a regular trapezoidal cross-sectional shape, an inverted trapezoidal cross-sectional shape, a rectangular cross-sectional shape or other suitable cross-sectional shapes. The second insulation layer has an inner surface 102IS adjacent to the second opening O2. The inner surface 102IS may connect the surface 102S2 and the other surface 102S1 of the second insulation layer 102. Corner edges connecting the inner surface 102IS and the surface 102S2 and the inner surface 102IS and the other surface 102S1 may be obtuse (or acute) corner edges, right-angle corner edges or arc-shaped corner edges.

In some embodiments, in the cross-section of the second insulation layer 102, the center of the second opening O2 and the outer surface 102S3 of the second insulation layer 102 are separated by a first distance X₁. Here, “the first distance X₁” refers to a distance between the center of the second opening O2 and the most protruding portion of the outer surface 102S3 at one end of the second insulation layer 102, which can be measured in the direction perpendicular to the Z-axis direction in the cross-section of the second insulation layer 102. In some embodiments, the maximum width W of the second opening O2 and the first distance X₁ may conform to the following formula: 1.5 W≤X₁<3 W, but are not limited thereto. In some embodiments, the maximum width W of the second opening O2 and the first distance X₁ may conform to the following formula: 1.7 W≤X₁≤2.8 W or 2 W≤X₁≤2.5 W.

In some embodiments, in the cross-section of the second insulation layer 102, the center of the second opening O2 and the other outer surface 102S4 of the second insulation layer 102 are separated by a second distance X₂. Here, “the second distance X₂” refers to a distance between the center of the second opening O2 and the most protruding portion of the other outer surface 102S4 at another end of the second insulation layer 102, which can be measured in the direction perpendicular to the Z-axis direction in the cross-section of the second insulation layer 102. In some embodiments, the first distance X₁ and the second distance X₂ may be the same or different. It should be noted that the first distance X₁ may be less than or equal to the second distance X₂. In some embodiments, the maximum width W of the second opening O2 and the second distance X₂ may conform to the following formula: 1.5 W≤X₂<3 W, but are not limited thereto. In some embodiments, the first distance X₁ and the second distance X₂ may conform to the following formula: 1≤X₂/X₁$4, or 1≤X₂/X₁≤3, or 1≤X>/X₁$2, or 1≤X₂/X₁≤1.8. By providing the second insulation layer 102 having the structure above, the circuit structure 10 of the present disclosure may have improved structural strength and/or supportability. The stress applied to the circuit structure 10 of the present disclosure may be distributed, thereby reducing the risk of cracking, damage or delamination of layers (such as the insulation layer) in the circuit structure 10.

In some embodiments, the conductive connection layer 105 may include a single-layer structure or a multi-layer structure. The conductive connection layer 105 may include seed layers, metals, or combination of the foregoing. In some embodiments, examples of the metals may include copper (Cu), aluminum (Al), molybdenum (Mo), tungsten (W), gold (Au), chromium (Cr), nickel (Ni), platinum (Pt), titanium (Ti), silver (Ag), tantalum (Ta), other suitable metal materials and any combination of the foregoing, but are not limited thereto.

In some embodiments, the conductive connection layer 105 is disposed in the second opening O2, and the conductive connection layer 105 may include a surface 105S2 and another surface 105S1. In some embodiments, the conductive connection layer 105 may contact the inner surface 102IS of the second insulation layer 102. In some embodiments, the surface 105S2 of the conductive connection layer 105 may be substantially level with the surface 101S2 of the first insulation layer 101 and/or the surface 102S2 of the second insulation layer 102. The other surface 105S1 of the conductive connection layer 105 may be substantially level with the other surface 101S1 of the first insulation layer 101 and/or the other surface 102S1 of the second insulation layer 102, but are not limited thereto. In some embodiments (not shown), the conductive connection layer 105 may extend to at least part of the surface 102S2 of the second insulation layer 102, at least part of the surface 101S2 of the first insulation layer 101, at least part of the other surface 102S1 of the second insulation layer 102, and/or at least part of the other surface 101S1 of the first insulation layer 101. In some embodiments, the second insulation layer 102 may surround an outer surface 105S3 of the conductive connection layer 105. In some embodiments, the outer surface 105S3 of the conductive connection layer 105 may be in contact with the inner surface 102IS of the second insulation layer 102. In some embodiments, when viewed in the Z-axis direction, an outline shape of the outer surface 105S3 of the conductive connection layer 105 is the same as the opening shape of the second opening O2. In some embodiments, a maximum width of the conductive connection layer 105 may be substantially the same as the maximum width W of the second opening O2, but is not limited thereto.

In some embodiments, the first insulation layer 101 and the second insulation layer 102 are disposed between the first conductive layer 107 and the second conductive layer 109. The first conductive layer 107 electrically connects the second conductive layer 109 by the conductive connection layer 105 provided in the first insulation layer 101 and the second insulation layer 102.

In some embodiments, the first conductive layer 107 contacts the surface 101S2 of the first insulation layer 101 and the surface 102S2 of the second insulation layer 102. The second conductive layer 109 contacts the other surface 101S1 of the first insulation layer 101 and the other surface 102S1 of the second insulation layer 102, as shown in FIG. 1A. The first conductive layer 107 and the second conductive layer 109 may include seed layers, metals, or a combination of the foregoing. In some embodiments, the metals may include copper (Cu), aluminum (Al), molybdenum (Mo), tungsten (W), gold (Au), chromium (Cr), nickel (Ni), platinum (Pt), titanium (Ti), silver (Ag), tantalum (Ta), other suitable metal materials and any combination of the foregoing, but are not limited thereto. The materials of the first conductive layer 107 may be the same as or different from that of the second conductive layer 109.

In some embodiments, the pad 50-1 and/or the solder structure 70 may be disposed on the second side 10S2 of the circuit structure 10 and be electrically connected to the circuit structure 10. In some embodiments, the pad 50-1 may include an under bump metallization (UBM) structure, a bump structure or a pad structure. In some embodiments, the pad 50-1 may include copper (Cu), aluminum (Al), molybdenum (Mo), tungsten (W), gold (Au), chromium (Cr), nickel (Ni), platinum (Pt), titanium (Ti), silver (Ag), tantalum (Ta), other suitable metal materials or any combination of the foregoing, but are not limited thereto. In some embodiments, the solder structure 70 may include solder balls, solder paste, such as tin paste, tin balls, or other solder structures, but is not limited thereto.

In some embodiments, the chip 30 may include a wafer, a die., or a packaged integrated circuit (IC). In some embodiments, the chip 30 may include passive elements and active elements, such as capacitors, resistors, inductors, diodes, transistors, etc. The diodes may include light-emitting diodes or photodiodes. See the description above for examples of the chip.

In some embodiments, the chip 30 disposed on the first side 10S1 of the circuit structure 10 may include a chip pad 301. The chip 30 can be electrically connected to the circuit structure 10 through the chip pad 301. In some embodiments, the chip pad 301 may include similar structures and materials to the conductive connection layer 105, but are not limited thereto. In some embodiments, an encapsulation layer M may cover the chip 30.

In some embodiments, the electronic device may include an insulation layer 110 disposed between the chip 30 and the second conductive layer 109. The insulation layer 110 may include an opening 110-0. The chip pad 301 may be disposed in the opening 110-O of the insulation layer 110.

In some embodiments, the electronic device may include an electronic element 20 disposed on the second side 10S2 of the circuit structure 10. The electronic element 20 may include passive elements, active elements, or a combination of the foregoing, such as capacitors, resistors, inductors, varactor diodes, variable capacitors, filters, diodes, transistors, sensors, microelectromechanical system (MEMS) elements, liquid crystal chips, etc., but are not limited thereto. The diodes may include light emitting diodes or non-light emitting diodes. The diodes may include P-N junction diodes, PIN diodes or constant current diodes. The light emitting diodes may include, for example, organic light emitting diodes (OLEDs), submillimeter light emitting diodes (mini LEDs), micro light emitting diodes (micro LEDs), quantum dot light emitting diodes (quantum dot LEDs), fluorescence diodes, phosphor diodes or other suitable materials, or any combination of the foregoing, but not limited thereto. The sensors may include, for example, capacitive sensors, optical sensors, electromagnetic sensors, fingerprint sensors (FPS), touch sensors, antennas, or pen sensors, etc., but are not limited to thereto. The electronic element 20 may include dies or LED dies, which may be a die made of silicon (Si), gallium arsenide (GaAs), gallium nitride (GaN), silicon carbide (SiC), sapphire or a glass substrate, but is not limited thereto. In another embodiment, the above-mentioned chips may include a semiconductor packaging element, such as a ball grid array (BGA) packaging element, a chip size package (CSP) element, a flip chip or a 2.5D/3-dimensional (2.5D/3D) semiconductor packaging element, but not limited thereto. In another embodiment, the chip may be any flip-chip bonding element, such as integrated circuits (ICs), transistors, controlled silicon rectifiers, valves, thin film transistors, capacitors, inductors, variable capacitors, filters, resistors, diodes, microelectromechanical system (MEMS) elements, liquid crystal chips, etc., but are not limited thereto.

In one embodiment, the solder structure 70 may be disposed between the electronic element 20 and the circuit structure 10. The electronic element 20 may include a pad 50-2. The pad 50-2 of the electronic element 20 and the pad 50-1 may be electrically connected to each other via the solder structure 70, as shown in FIG. 1A, but is not limited thereto. The pad 50-2 of the electronic element 20 and the pad 50-1 may be electrically connected through other methods.

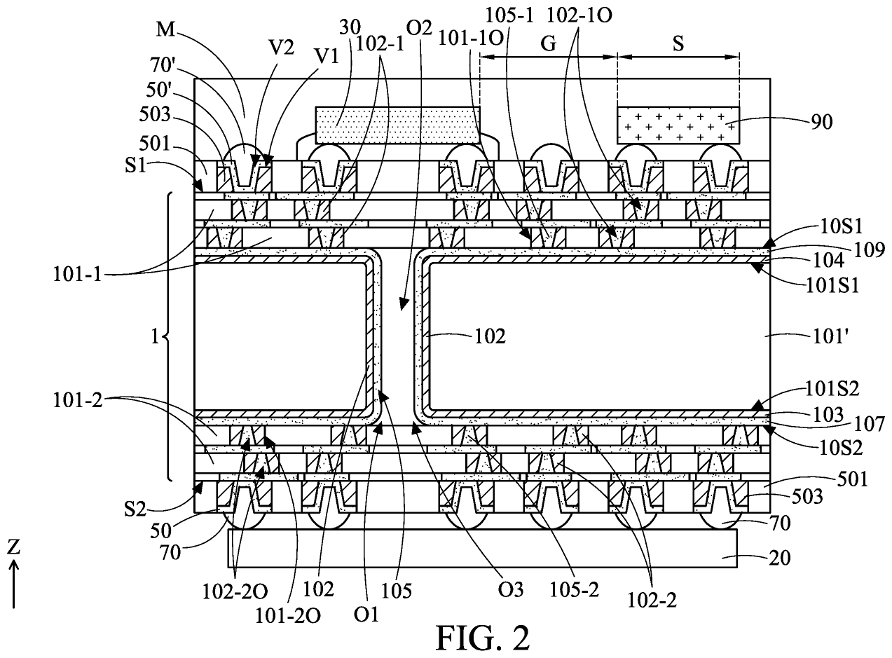

FIG. 2 is a schematic cross-sectional view of an electronic device according to another embodiment of the present disclosure. As shown in FIG. 2, an electronic device according to an embodiment of the present disclosure may include a circuit structure 1. The circuit structure 1 has a first side S1 and a second side S2 that are opposite to each other. The electronic device includes a chip 30 and a solder structure 70′ disposed on the first side S1 of the circuit structure 1. The electronic device may include a pad 50′ disposed on the first side S1 of the circuit structure 1. The chip 30 is electrically connected to the pad 50′ through the solder structure 70′. The electronic device may include an electronic element 20 and a solder structure 70 disposed on the second side S2 of the circuit structure 1. The electronic device may include a pad 50 disposed on the second side S2 of the circuit structure 1. The electronic element 20 may be electrically connected to the pad 50 through the solder structure 70. The solder structure 70 may, for example, contact the pad 50.

The solder structure 70′ and the solder structure 70 in the electronic device shown in FIG. 2 may be made of similar materials. The materials of the solder structure 70′ and the solder structure 70 may be referred to the description in FIG. 1A above.

As shown in FIG. 2, the circuit structure 1 may include a multi-layer structure in which multiple insulation layers and conductive layers are stacked. Adjacent conductive layers in the multi-layer structure may be electrically connected, for example, through a conductive connection layer disposed in an opening of the insulation layer. Details of the circuit structure 1 are described below. In some embodiments, the circuit structure 1 may include a multi-layer structure including first insulation layers 101-1 and conductive layers. Two conductive layers (as the layers shown in the dotted shadow in the drawing) are disposed respectively on opposite surfaces of each first insulation layer 101-1. The first insulation layer 101-1 includes a first opening 101-10, a second insulation layer 102-1 is disposed in the first opening 101-10 and includes a second opening 102-10. The conductive connection layer 105-1 is disposed in the second opening 102-10 of the second insulation layer 102-1. The two conductive layers (as the layers shown in the dotted shadow in the drawing) that are disposed on opposite surfaces (not shown) of the first insulation layer 101-1 may be electrically connected, for example, through a conductive connection layer 105-1. In some embodiments, the circuit structure 1 may include a multi-layer structure including first insulation layers 101-2 and conductive layers. Two conductive layers (as the layers shown in the dotted shadow in the drawing) are disposed respectively on opposite surfaces of each first insulation layer 101-2. The first insulation layer 101-2 includes a first opening 101-20, and a second insulation layer 102-2 is disposed in the first opening 101-20 and includes a second opening 102-20. A conductive connection layer 105-2 is disposed in the second opening 102-20 of the second insulation layer 102-2. The two conductive layers (as the layers shown in the dotted shadow in the drawing) that are disposed on opposite surfaces (not shown) of the first insulation layer 101-2 may be electrically connected, for example, through the conductive connection layer 105-2. In some embodiments, the Young's modulus of the second insulation layer 102-1 is less than the Young's modulus of the first insulation layer 101-1. In some embodiments, the Young's modulus of the second insulation layer 102-2 is less than the Young's modulus of the first insulation layer 101-2. In a cross-section of the electronic device, the second opening 102-10 of the second insulation layer 102-1 has a maximum width (not shown). The center of the second opening 102-10 and the outer surface of the second insulation layer 102-1 are separated by a first distance (not shown in FIG. 2, refer to the definition of X1 in FIG. 1A). The maximum width of the second opening 102-10 (not shown in FIG. 2, refer to the definition of W in FIG. 1A) and the first distance X₁ conform to the following formula: 1.5 W≤X₁<3 W. In a cross-section of the electronic device, the second opening 102-20 of the second insulation layer 102-2 has a maximum width (not shown). The center of the second opening 102-20 and the outer surface of the second insulation layer 102-2 are separated by a first distance (not shown in FIG. 2, refer to the definition of X₁ in FIG. 1A). The maximum width of the second opening 102-20 (not shown in FIG. 2, refer to the definition of W in FIG. 1A) and the first distance X₁ conform to the following formula: 1.5 W≤X₁<3 W. Examples of the material of the first insulation layer 101-1 or the first insulation layer 101-2 may refer to that of the first insulation layer 101 above. For examples of materials of the second insulation layer 102-1 or the second insulation layer 102-2 may refer to that of the second insulation layer 102 above.

In some embodiments, as shown in FIG. 2, the circuit structure 1 may further include a first insulation layer 101′, a second insulation layer 102, a third insulation layer 103, a fourth insulation layer 104, a conductive connection layer 105, a first conductive layer 107 and a second conductive layer 109. In some embodiments, the first insulation layer 101′ includes a first opening O1 and a surface 101S2 and another surface 101S1 that are opposite to each other. The second insulation layer 102 is disposed in the first opening O1 and includes the second opening O2. The conductive connection layer 105 is disposed in the second opening O2. The first conductive layer 107 is disposed on the surface 101S2 of the first insulation layer 101′. The second conductive layer 109 is disposed on the other surface 101S1 of the first insulation layer 101. The first conductive layer 107 is electrically connected to the second conductive layer 109 by the conductive connection layer 105. The surface 101S2 and the other surface 101S1 are opposite to each other. In some embodiments, the third insulation layer 103 is disposed between the first conductive layer 107 and the surface 101S2 of the first insulation layer 101′. The fourth insulation layer 104 is disposed between the second conductive layer 109 and the other surface 101S1 of the first insulation layer 101 ‘. In some embodiments, a corner edge connected between the second insulation layer 102 and the third insulation layer 103 and/or the fourth insulation layer 104 may be an arc corner edge, a right angle corner edge or a bevel corner edge. In other words, a corner edge of the first opening O1 in the first insulation layer 101’ may be an arc corner edge, a right angle corner edge or a bevel corner edge.

In some embodiments, the Young's modulus of the third insulation layer 103 may be less than that of the first insulation layer 101′, and the Young's modulus of the fourth insulation layer 104 may be less than that of the first insulation layer 101′. In some embodiments, the third insulation layer 103 and the fourth insulation layer 104 may include insulation materials having a Young's modulus that is between 0.1 Gpa and 10 Gpa, between 0.1 Gpa and 8 Gpa, or between 0.5 Gpa and 7 Gpa. In some embodiments, the materials of the second insulation layer 102, the third insulation layer 103 and/or the fourth insulation layer 104 in FIG. 2 may refer to that of the second insulation layer 102 above. The materials of the second insulation layer 102, the third insulation layer 103 and/or the fourth insulation layer 104 may be the same or different from each other.

In some embodiments, as shown in FIG. 2, the conductive connection layer 105 may have a third opening O3, but is not limited thereto. In some embodiments, the third opening O3 may be filled with conductive materials or insulation materials. In some embodiments, the third opening O3 may not be filled with materials. In some embodiments, the first insulation layer 101′ be used as a substrate. For example, if the first insulation layer 101′ includes glass, polyimide (PI) or other substrate materials, the first opening O1 may be a through glass via (TGV), a through PI via (TPV) or other suitable through holes, but are not limited thereto. In some embodiments, the first opening O1 of the first insulation layer 101′ is formed, for example, by laser or other suitable methods.

In some embodiments, the first insulation layer 101′ may be disposed, for example, between the first insulation layer 101-1 and the first insulation layer 101-2. In some embodiments, a thickness of the first insulation layer 101′ may be greater than a thickness of the first insulation layer 101-1 and/or a thickness of the first insulation layer 101-2. In some embodiments, a hardness of the first insulation layer 101′ may be greater than a hardness of the first insulation layer 101-1 and/or a hardness of the first insulation layer 101-2.

In some embodiments, as shown in FIG. 2, the electronic device may include an insulation layer 501 and an insulation layer 503. In some embodiments, the insulation layer 501 and the insulation layer 503 may be disposed between the first insulation layer 101-1 and the chip 30, for example. In some embodiments, the insulation layer 501 and the insulation layer 503 may be disposed between the first insulation layer 101-2 and the electronic element 20, for example. The insulation layer 501 includes a first pad opening V1. The insulation layer 503 is disposed in the first pad opening V1 and includes a second pad opening V2. The pad 50′ may be electrically connected to the chip 30. The pad 50 may be electrically connected to the electronic element 20. The pad 50′ may be disposed in the second pad opening V2 and electrically connected to the conductive layer (not shown) of the circuit structure 1. The pad 50 may be disposed in the second pad opening V2 and electrically connected to the conductive layer (not shown) of the circuit structure 1.

Similarly, in a cross-section of the electronic device, the second pad opening V2 of the insulation layer 503 may have a maximum width (not shown). The center of the second pad opening V2 and the outer surface of the insulation layer 503 are separated by a first distance (not shown in FIG. 2, refer to the definition of X₁ in FIG. 1A). The maximum width of the second pad opening V2 (not shown in FIG. 2, refer to the definition of W in FIG. 1A) and the first distance X₁ conform to the following formula: 1.5 W≤X₁<3 W. In some embodiments, the maximum width of the second pad opening V2 (not shown in FIG. 2, refer to the definition of W in FIG. 1A) and the first distance (not shown in FIG. 2, refer to the definition of X₁ in FIG. 1A) conform to the following formula: 1.7 W≤X₁≤2.8 W or 2 W≤X₁≤ 2.5 W.

In some embodiments, the risk of cracking, damage or delamination of the insulation layer 501 in the electronic device due to the difference in thermal expansion coefficient between the insulation layer 501 and the pad 50′ (or the pad 50) can be reduced by disposing the insulation layer 503 between the pad 50′ (or the pad 50) and the insulation layer 501. The insulation layer 503 is disposed corresponding to the pad 50′ (or the pad 50). Therefore, the electronic device maintains better structural strength and sufficient support.

In some embodiments, the electronic device may include a surface mount device (SMD) 90 disposed on the first side 10S1, but is not limited thereto. As shown in FIG. 2, the surface mount device 90 may be electrically connected to the pad 50′, for example, through the solder structure 70′. The surface mount device 90 may be disposed adjacent to the chip 30. The surface mount device 90 may be disposed coplanar with the chip 30, but is not limited thereto. In some embodiments, the surface mount device 90 may have a width S (maximum width) in a direction perpendicular to the Z-axis direction. A distance (minimum distance) between the surface mount device 90 and the chip 30 may be defined as a space G. The space G may be greater than or equal to the width S to reduce an electrical interference between the surface mount device 90 and the chip 30. In some embodiments, the surface mount device 90 may include, for example, passive elements, active elements, or a combination of the foregoing, such as capacitors, resistors, inductors, varactor diodes, variable capacitors, filters, diodes, transistors, sensors, microelectromechanical system (MEMS) elements, liquid crystal chips, etc., but are not limited thereto.

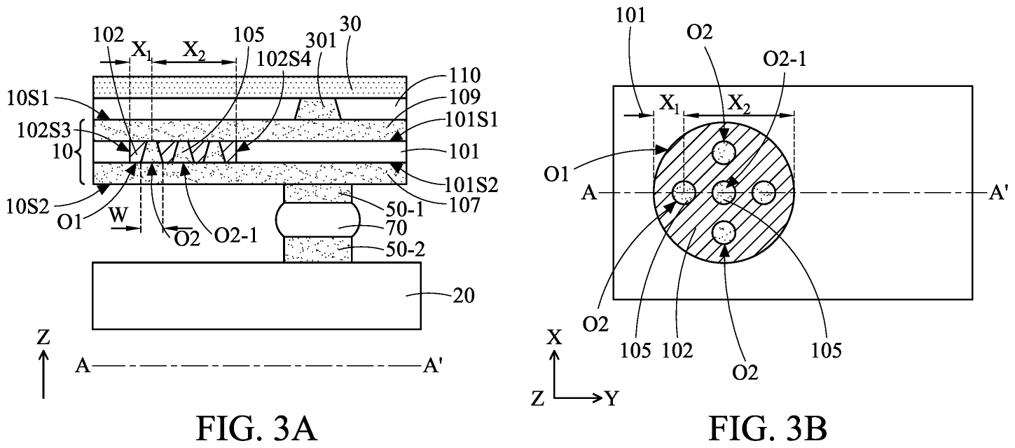

FIG. 3A is a schematic cross-sectional view of an electronic device according to another embodiment of the present disclosure. FIG. 3A is a schematic cross-sectional view, for example, generally taken along a line A-A′ of FIG. 3B. FIG. 3B is a schematic top view of the first insulation layer 101 according to an embodiment of the present disclosure. As can be seen from FIG. 3A and FIG. 3B, the first insulation layer 101 includes a first opening O1 and a surface 101S2 and another surface 101S1 that are opposite to each other. The second insulation layer 102 is disposed in the first opening O1 and includes a plurality of second openings (for example, the second openings O2 and the second opening O2-1). The circuit structure 10 includes a plurality of conductive connection layers 105. The second insulation layer 102 includes a plurality of second openings (such as the second openings O2 and the second opening O2-1). The conductive connection layers 105 are disposed in the respective second openings (such as the second openings O2 and the second opening O2-1). In some embodiments, the second openings (e.g., the second openings O2 and the second opening O2-1) may have the same or different shapes and sizes. As shown in FIG. 3B, the second openings O2 may, for example, surround the second opening O2-1, but is not limited thereto. These second openings O2 are closer to the outer surface 102S3 (or the outer surface 102S4) of the second insulation layer 102 than the second openings O2-1. The arrangement of the second openings (e.g., the second opening O2 and the second opening O2-1) shown in FIG. 3B is only an example. The second openings may be arranged in an array or other irregular arrangement. Except that the circuit structure 10 including a plurality of conductive connection layers 105 and the second insulation layer 102 including a plurality of second openings (such as the second openings O2 and the second opening O2-1), the electronic device shown in FIG. 3A is substantially the same as the electronic device shown in FIG. 1, so no further description will be given here. In some embodiments, the center of the second opening O2 and the outer surface 102S3 of the second insulation layer 102 that adjacent to the second opening O2 are separated by a first distance X₁. The maximum width W of the second opening O2 and the first distance X₁ conform to the following formula: 1.5 W≤X₁<3 W. It should be noted that, when the second insulation layer 102 disposed in the first opening O1 includes a plurality of second openings, the definitions of the maximum width W and the first distance X₁ of one of the second openings O2 adjacent to the outer surface of the second insulation layer 102, for example, the left second opening O2 (as shown in FIG. 3A or 3B), may refer to the above. In addition, taking the left second opening O2 as an example, a distance between the center of the second opening O2 and the most protruding portion of the outer surface 102S3 at one end of the second insulation layer 102 measured in the direction perpendicular to the Z-axis direction in the cross-section of the second insulation layer 102 is defined as a first distance X₁. A distance between the center of the second opening O2 and the most protruding portion of the other outer surface 102S4 at the other end of the second insulation layer 102 measured in the direction perpendicular to the Z-axis direction in the cross-section of the second insulation layer 102 is defined as a second distance X₂. The first distance X₁ is smaller than the second distance X₂. In the circuit structure 10 shown in FIG. 1 or FIG. 3B, the second opening O2 of the second insulation layer 102 may not overlap the solder structure 70, but is not limited thereto. The overlapping of an element A and an element B may be defined as that the element A and the element B at least partially overlap each other in the Z-axis direction (the direction in which the electronic device is viewed from above). In some embodiments, the second opening O2 of the second insulation layer 102 may not overlap the solder structure 70. FIGS. 4A to 4D are schematic cross-sectional views of circuit structures, pads, and solder structures according to some embodiments of the present disclosure. The positional relationship between the circuit structure, chip pads, pads and solder structure of the present disclosure will be further described below with reference to FIGS. 4A to 4D.

FIG. 4A shows a circuit structure 10A, a chip pad 301 disposed on a first side 10S1 of the circuit structure 10A, a pad 50-1 and a pad 50-2 disposed on a second side 10S2 of the circuit structure 10A, and a solder structure 70 disposed between the pad 50-1 and the pad 50-2 and in contact with the pad 50-1 and the pad 50-2. The circuit structure 10A shown in FIG. 4A is substantially the same as the circuit structure 10 of FIG. 1 except that the first opening O1 of the first insulation layer 101 has a regular trapezoidal cross-section. In some embodiments, the chip pad 301 overlaps the conductive connection layer 105 and the second opening O2 in the Z-axis direction. In some embodiments, the center of the conductive connection layer 105 may substantially overlap the center of the second opening O2 (i.e., centers thereof are coaxial), but is not limited thereto. In some embodiments, the solder structure 70 is disposed on the second side 10S2 of the circuit structure 10A. In the Z-axis direction, the solder structure 70 may overlap with the chip pad 301, the conductive connection layer 105 and/or the second opening O2, for example. In some embodiments, the center of the solder structure 70 substantially overlaps the center of the chip pad 301, the center of the conductive connection layer 105 and/or the center of the second opening O2 (i.e., centers of the conductive connection layer 105 and the second opening O2 are coaxial). It should be noted that when referring to the center of an element, if an outline of the element is circular, the center of the element is the center of the circular outline. If the outline of the element is irregular, the center of the element may be, for example, the point of intersection of two diagonal lines of a minimum rectangle outlining the element.

FIG. 4B shows a circuit structure 10B, a chip pad 301 disposed on a first side 10S1 of the circuit structure 10B, a pad 50-1 and a pad 50-2 disposed on a second side 10S2 of the circuit structure 10B, and a solder structure 70 disposed between the pad 50-1 and the pad 50-2 and in contact with the pad 50-1 and the pad 50-2. The circuit structure 10B shown in FIG. 4B is substantially the same as the circuit structure 10 of FIG. 1 except that the first opening O1 of the first insulation layer 101 has an inverted trapezoidal cross-section. In some embodiments, in the Z-axis direction, the chip pad 301 does not overlap with the conductive connection layer 105 and the second opening O2. In some embodiments, the center of the chip pad 301 does not overlap with the center of the conductive connection layer 105 and the center of the second opening O2 (i.e., centers thereof are not coaxial). In some embodiments, in the Z-axis direction, the solder structure 70 overlaps the conductive connection layer 105 and the second opening O2. In some embodiments, in the Z-axis direction, the center of the solder structure 70 substantially overlaps with the center of the conductive connection layer 105 and the center of the second opening O2 (i.e., centers thereof are coaxial).

FIG. 4C shows a circuit structure 10C, a chip pad 301 disposed on a first side 10S1 of the circuit structure 10C, a pad 50-1 and a pad 50-2 disposed on a second side 10S2 of the circuit structure 10C, and a solder structure 70 disposed between the pad 50-1 and the pad 50-2 and in contact with the pad 50-1 and the pad 50-2. The circuit structure 10C shown in FIG. 4C is substantially the same as the circuit structure 10 of FIG. 1 except that the first opening O1 of the first insulation layer 101 has a cross-section having convex curved sides. In some embodiments, the chip pad 301 overlaps the conductive connection layer 105 in the Z-axis direction. In some embodiments, in the Z-axis direction, the center of the chip pad 301 substantially overlaps the center of the conductive connection layer 105 (i.e., centers thereof are coaxial). In some embodiments, the solder structure 70 does not overlap the conductive connection layer 105 and the second opening O2 in the Z-axis direction. In some embodiments, in the Z-axis direction, the center of the solder structure 70 does not overlap the center of the conductive connection layer 105 and the center of the second opening O2 (i.e., they are not coaxial).

FIG. 4D shows a circuit structure 10D, a chip pad 301 disposed on a first side 10S1 of the circuit structure 10C, a pad 50-1 and a pad 50-2 disposed on a second side 10S2 of the circuit structure 10C, and a solder structure 70 disposed between the pad 50-1 and the pad 50-2 and in contact with the pad 50-1 and the pad 50-2. The circuit structure 10D shown in FIG. 4D is substantially the same as the circuit structure 10 of FIG. 1 except that the first opening O1 of the first insulation layer 101 has a cross-section having concave curved sides. In some embodiments, in the Z-axis direction, the chip pad 301 does not overlap the conductive connection layer 105 and the second opening O2. In some embodiments, in the Z-axis direction, the center of the chip pad 301 does not overlap with the center of the conductive connection layer 105 and the center of the second opening O2 (i.e., centers thereof are not coaxial). In some embodiments, the solder structure 70 overlaps the die pad 301 in the Z-axis direction. In some embodiments, in the Z-axis direction, the center of the solder structure 70 substantially overlaps the center of the chip pad 301 (i.e., centers thereof are coaxial).

In the above embodiments of FIGS. 4A to 4D, by disposing the second insulation layer 102 having a Young's modulus that is smaller than that of the first insulation layer 101 between the first insulation layer 101 and the conductive connection layer 105, the circuit structure provided by the present disclosure may have better structural strength and sufficient support. In the above embodiment of FIGS. 4A to 4D, in a cross-section of the electronic device, the second opening O2 of the second insulation layer 102 has a maximum width W (not shown in FIGS. 4A to 4D, please refer to the definition of W in FIG. 1A). The center of the second opening O2 and the outer surface of the second insulation layer 102 are separated by a first distance X₁. The maximum width W of the second opening O2 and the first distance X₁ conform to the following formula: 1.5 W≤X₁<3 W. The stress applied to the circuit structure of the present disclosure may be distributed, thereby reducing the risk of cracking, damage or delamination of layers in the circuit structure by the feature above.

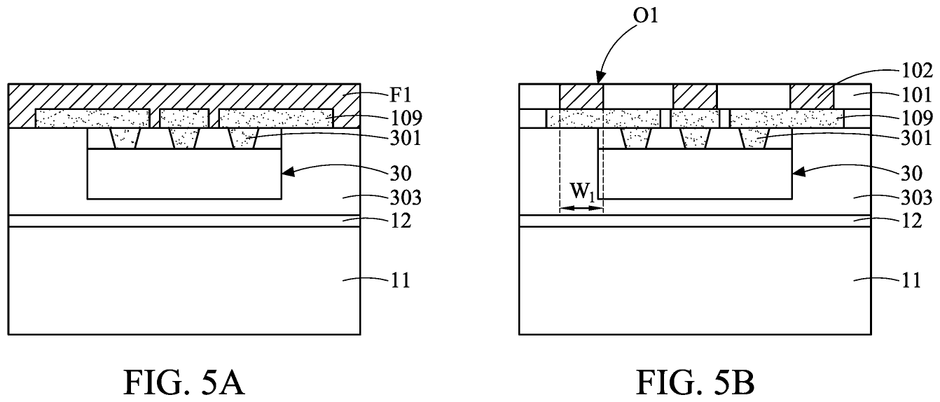

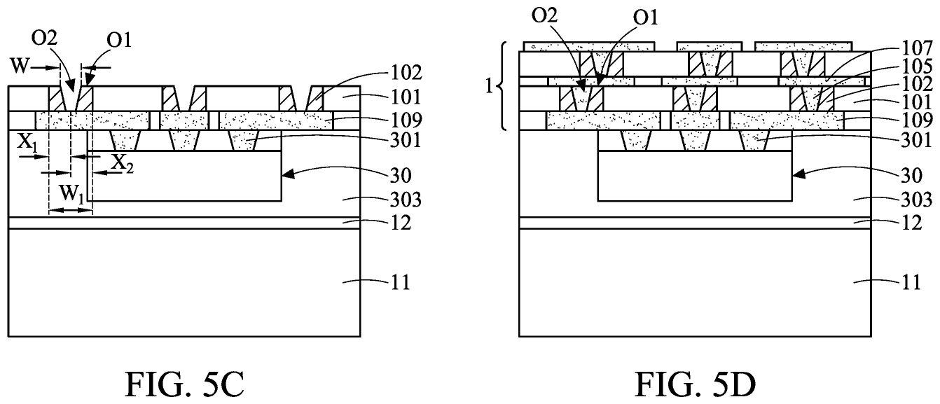

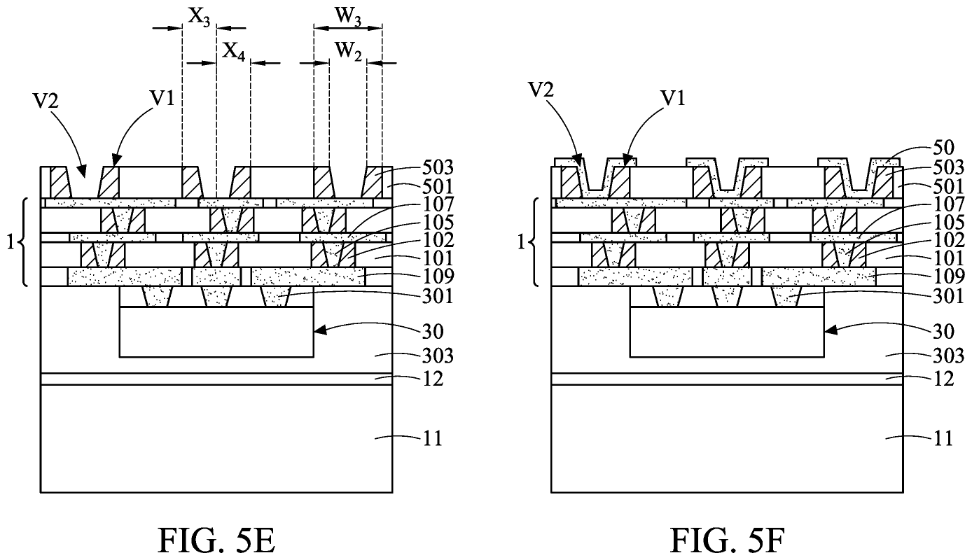

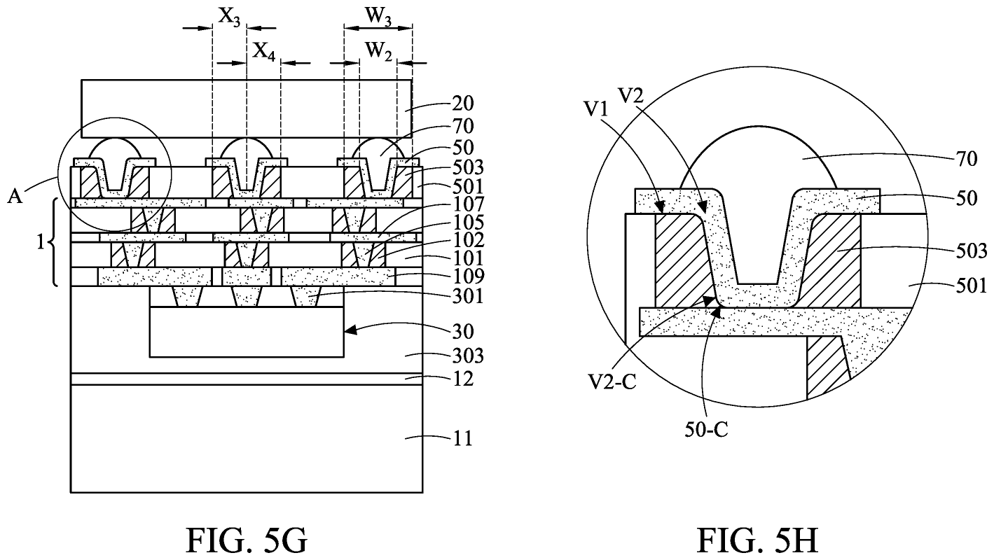

FIGS. 5A to 5G are cross-sectional views of an electronic device during preparation of the electronic device according to some embodiments of the present disclosure. FIG. 5H is an enlarged view of an area A in FIG. 5G. The following describes the preparation process of the electronic device according to some embodiments of the present disclosure with reference to FIGS. 5A to 5G.

According to the preparation process of the electronic device according to some embodiments of the present disclosure, the chip 30 (having the chip pad 301) is provided in an encapsulation layer 303, wherein the chip pads 301 are exposed. The chip 30 and the encapsulation layer 303 are disposed on a carrier substrate 11 on which a release layer 12 is provided. The release layer 12 may include an adhesive material, such as an adhesive material that can be separated by laser, light or thermal cracking, but it is not limited thereto. The encapsulation layer 303 covers an integrated circuit (not shown) in the chip 30. The encapsulation layer 303 may expose part of the surface of the chip pad 301. The second conductive layer 109 may be disposed on the chip 30, the chip pad 301 and the encapsulation layer 303. The second conductive layer 109 may be electrically connected to the chip pad 301, for example. The chip 30, the chip pads 301 and the encapsulation layer 303 may be disposed between the second conductive layer 109 and the release layer 12. An insulation layer F1, for example, is provided on the second conductive layer 109, and the resulting structure is as shown in FIG. 5A. In some embodiments, the insulation layer F1 includes any insulation material having a Young's modulus that is within a range of 0.1 Gpa to 10 Gpa, but it is not limited thereto. In some embodiments, the insulation layer F1 may include materials that are similar to that of the second insulation layer 102 above.

After patterning the insulation layer F1 shown in FIG. 5A to form the second insulation layer 102 (as described above), the first insulation layer 101 is disposed on the patterned second insulation layer 102. In this stage, the second insulation layer 102 is, for example, disposed in the first opening O1 of the first insulation layer 101. The resulting structure is shown in FIG. 5B.

A laser process is used to form a second opening O2 penetrating the second insulation layer 102 and having a maximum width W in the second insulation layer 102 shown in FIG. 5B. The resulting structure is shown in FIG. 5C. In a cross-section of the electronic device, the maximum width W of the second opening O2 and the maximum outline width W₁ of the second insulation layer 102 conform to the following formula: 3 W≤W₁<6 W or 3.5 W≤W₁<5.5 W or 4 W≤W₁<5 W. The center of the second opening O2 is separated from the outer surface (not shown) of the second insulation layer 102 by a first distance X₁. The center of the second opening O2 is separated from the other outer surface (not shown) of the second insulation layer 102 by a second distance X₂. The first distance X₁ may be the same as or different from the second distance X₂. The first distance X₁ is less than or equal to the second distance X₂, and the ratio of the first distance X₁ to the second distance X₂ may be referred to the description of FIG. 1A.

A conductive material is then formed in the second opening O2 of the second insulation layer 102 to prepare the conductive connection layer 105 and a patterned first conductive layer 107 electrically connected to the conductive connection layer 105. The above preparation process may repeat several times to form circuit structure 1, as shown in FIG. 5D.

An insulation layer 501 is provided on the structure of FIG. 5D in the same way as FIGS. 5A to 5C. The insulation layer 501 includes the first pad opening V1. An insulation layer 503 is disposed in the first pad opening V1 of the insulation layer 501, wherein the insulation layer 503 includes the second pad opening V2. The resulting structure is shown in FIG. 5E. The insulation layer 501 and the first pad opening V1 may be similar to the first insulation layer 101 and the first opening O1. The insulation layer 503 and the second pad opening V2 of the insulation layer 503 may be similar to the second insulation layer 102 and the second opening O2. That is, the Young's modulus of the insulation layer 503 is smaller than the Young's modulus of the insulation layer 501. In a cross-section of the electronic device, the insulation layer 503 has a maximum outline width W₃, and the second pad opening V2 has a maximum width W₂. The maximum width W₂ of the second pad opening V2 of the insulation layer 503 and the maximum outline width W₃ of the insulation layer 503 conform to the following formula: 3W₂≤W₃<6W₂, or 3.5W₂≤W₃<5.5W₂, or 4W₂≤W₃<5W₂. The center of the second pad opening V2 and the outer surface (not shown) of the insulation layer 503 are separated by a third distance X₃. The center of the second pad opening V2 and the other outer surface (not shown) of the insulation layer 503 are separated by fourth distance X₄. The third distance X₃ may be the same as or different from the fourth distance X₄. The maximum width W₂ of the second pad opening V2 and the third distance X₃ conform to the following formula: 1.5W₂₅X₃<3W₂, or 1.7 W₂₅X₃≤2.8 W₂. The maximum width W₂ of the second pad opening V2 and the fourth distance X₄ conform to the following formula: 1.5W₂≤X_{4<3}W₂, or 1.7 W₂≤X_{4≤2.8} W₂.

The pad 50 is disposed in the second pad opening V2 of the insulation layer 503. The resulting structure is shown in FIG. 5F. Finally, after disposing the solder structure 70 in contact with the pad 50 on the structure shown in FIG. 5F, the electronic element 20 is disposed. The electronic element 20 and the pad 50 are electrically connected through the solder structure 70 to complete the preparation of the electronic device of the present disclosure. The structure of the resulting electronic device is shown in FIG. 5G.

FIG. 5H is an enlarged view of an area A in FIG. 5G. It may be clearly seen from FIG. 5H that the second pad opening V2 may have an arc-shaped corner edge V2-C, and the pad 50 disposed in the second pad opening V2 may have an arc-shaped corner edge 50-C.

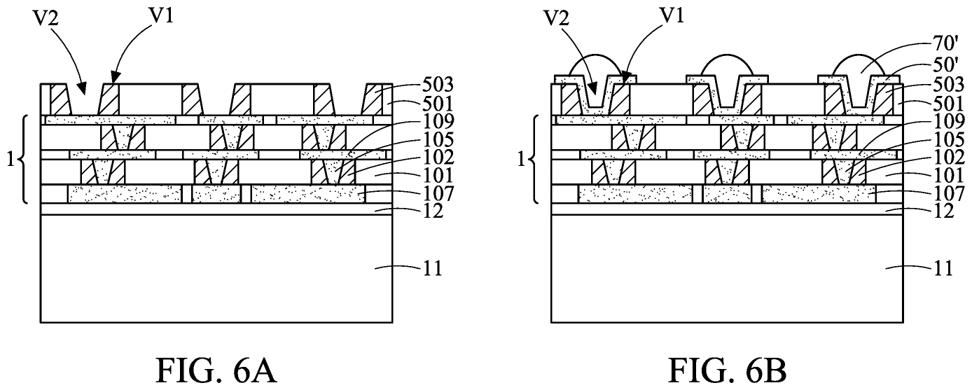

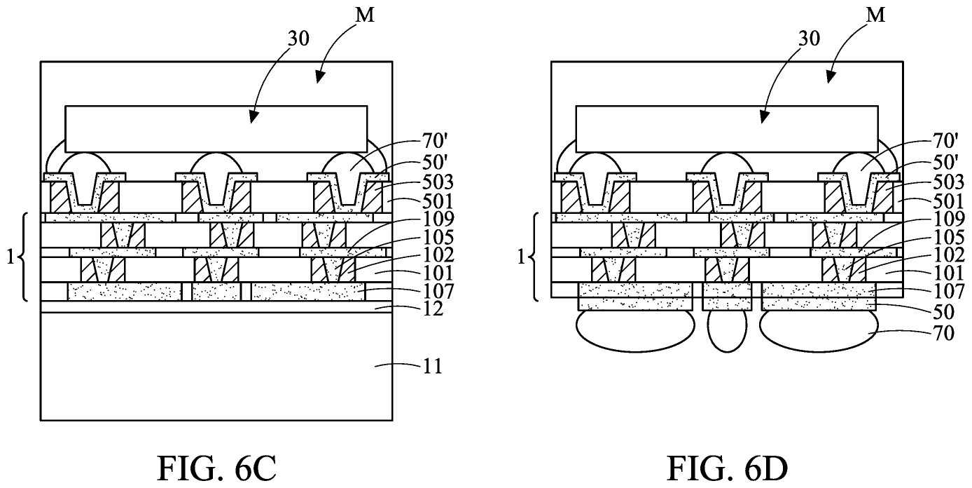

FIGS. 6A to 6D are cross-sectional views of an electronic device during the preparation of the electronic device according to other embodiments of the present disclosure. The following describes the preparation process of electronic devices according to other embodiments of the present disclosure with reference to FIGS. 6A to 6D.

The preparation process of the electronic device according to some embodiments of the present disclosure includes disposing a release layer 12 on a carrier substrate 11. A circuit are provided in a way and material similar to that shown in FIGS. 5A to 5C. The resulting structure is shown in FIG. 6A. A pad 50′ and a solder structure 70′ in contact with the pad 50′ are provided in the second pad opening V2 of the insulation layer 503. The resulting structure is as shown in FIG. 6B. The chip 30 is disposed on the pad 50′ and the solder structure 70′. The pad 50′ is electrically connected to the chip 30 through the solder structure 70′. An encapsulation layer M is disposed on the chip 30 and covers the chip 30. The resulting structure is shown in FIG. 6C.

The release layer 12 and the carrier substrate 11 are removed from the structure shown in FIG. 6C to expose the first conductive layer 107 in the circuit structure 1. A solder structure 70 is disposed on a pad 50 after disposing the pad 50 on the first conductive layer 107. The resulting structure is shown in FIG. 6D. The electronic element (not shown, refer to the electronic element in FIG. 1A) may be electrically connected to the pad 50 through the solder structure 70. The solder structure 70 may be selectively bonded to the electronic element later to complete the preparation of the electronic device of the present disclosure.

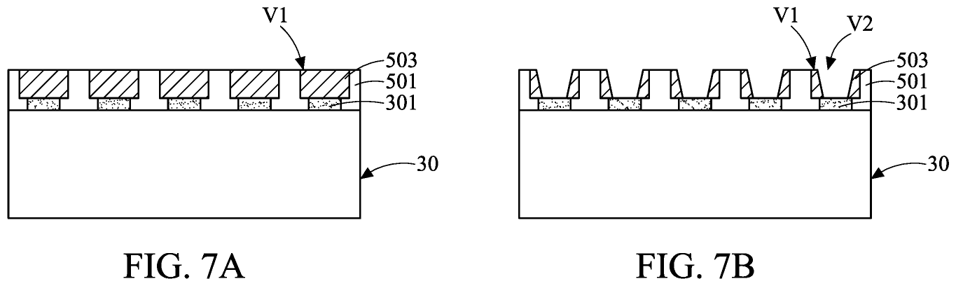

In some embodiments, FIG. 7A and FIG. 7B are cross-sectional views of an electronic device during the preparation of the electronic device according to other embodiments of the present disclosure.

The preparation process of the electronic device according to some embodiments of the present disclosure includes forming an insulation layer 501 including a first pad opening V1 on the chip pad 301 of the chip 30 and an insulation layer 503 disposed in the first pad opening V1 in a way similar to that shown in FIG. 5A and FIG. 5B. The resulting structure is shown in FIG. 7A. The second pad opening V2 may be formed in a similar way to that formed the second pad opening V2, and therefore it will not be described again. Subsequently, other conductive layers (such as the second conductive layer 109) may be disposed in the second pad opening V2, and the circuit structure 10 and/or the pad 50 may be disposed in a similar way to that shown in FIGS. 5A to 5G to complete the preparation of the electronic device of the present disclosure.

The present disclosure may prepare a circuit structure that has better structural strength and sufficient support while distributing stress applied to the circuit structure and reducing the risk of cracking, damage or delamination of layers in the circuit structure by the above preparation method.

While the disclosure has been described by way of example and in terms of the preferred embodiments, it should be understood that the disclosure that changes, substitutions and modifications may be made without departing from the spirit and scope of the disclosure. In addition, the protection scope of the present disclosure is not limited to the processes, machines, fabrications, compositions, devices, methods and steps in the specific embodiments described in the specification. According to the embodiments of the present disclosure, a person of ordinary skill in the art may understand that current or future processes, machines, fabrications, compositions, devices, methods and steps capable of performing substantially the same functions or achieving substantially the same results may be used in the embodiments of the present disclosure. Therefore, the protection scope of the present disclosure includes the above-mentioned processes, machines, fabrications, compositions, devices, methods and steps. In addition, features of different embodiments may be used together arbitrary as long as they do not violate the spirit of the disclosure or conflict with each other. Each claim constitutes an individual embodiment, and the protection scope of the present disclosure includes the combination of the claims and embodiments.

What is claimed is:

1. An electronic device, comprising:
a circuit structure having a first side and a second side that are opposite to each other, wherein the circuit structure comprises:
a first insulation layer having a first opening and a surface and another surface that are opposite to each other;
a second insulation layer disposed in the first opening and having a second opening;
a conductive connection layer disposed in the second opening;
a first conductive layer disposed on the surface of the first insulation layer; and
a second conductive layer disposed on the other surface of the first insulation layer, wherein the first conductive layer and the second conductive layer are electrically connected to each other by the conductive connection layer;
a chip disposed on the first side of the circuit structure;
a pad disposed on the second side of the circuit structure; and
a solder structure contacting the pad,
wherein a Young's modulus of the second insulation layer is smaller than a Young's modulus of the first insulation layer,
wherein in a cross-section of the electronic device, the second opening has a maximum width W, a center of the second opening and an outer surface of the second insulation layer are separated by a first distance X₁, and the maximum width W of the second opening and the first distance X₁ conform to the following formula:
1.5 X the maximum width W≤the first distance X₁<3 X the maximum width W.

2. The electronic device as claimed in claim 1, wherein the first insulation layer surrounds the outer surface of the second insulation layer.

3. The electronic device as claimed in claim 1, wherein the first conductive layer contacts the surface of the first insulation layer and a surface of the second insulation layer, and the second conductive layer contacts the other surface of the first insulation layer and another surface of the second insulation layer.

4. The electronic device as claimed in claim 1, wherein the second insulation layer has a maximum outline width W₁, and the maximum width W of the second opening and the maximum outline width W₁ conform to the following formula:
3 X the maximum width W≤ maximum outline width W₁<6 X the maximum width W.

5. The electronic device as claimed in claim 1, wherein the Young's modulus of the second insulation layer is between 0.1 Gpa and 10 Gpa.

6. The electronic device as claimed in claim 1, wherein a ratio of the Young's modulus of the second insulation layer to the Young's modulus of the first insulation layer is greater than 1 and less than or equal to 10.

7. The electronic device as claimed in claim 1, wherein the first insulation layer comprises glass or polyimides.

8. The electronic device as claimed in claim 7, wherein the first opening comprises a through glass via (TGV) or a through PI via (TPV).

9. The electronic device as claimed in claim 1, wherein the circuit structure further comprises:
a third insulation layer disposed between the first conductive layer and the surface of the first insulation layer; and
a fourth insulation layer disposed between the second conductive layer and the other surface of the first insulation layer,
wherein a Young's modulus of the third insulation layer and a Young's modulus of the fourth insulation layer are less than the Young's modulus of the first insulation layer.

10. The electronic device as claimed in claim 9, wherein the third insulation layer and the fourth insulation layer comprise an insulation material having a Young's modulus between 0.1 Gpa and 10 Gpa.

11. The electronic device as claimed in claim 1, wherein the circuit structure comprises a plurality of the conductive connection layers, the second insulation layer comprises a plurality of the second openings, and the plurality of conductive connection layers are respectively disposed in the plurality of second openings.

12. The electronic device as claimed in claim 1, wherein the second opening overlaps the solder structure.

13. The electronic device as claimed in claim 1, wherein the second opening does not overlap the solder structure.

14. The electronic device as claimed in claim 1, wherein the conductive connection layer has a third opening, and the third opening is filled with conductive materials or insulation materials.

15. The electronic device as claimed in claim 1, wherein the conductive connection layer has a third opening, and the third opening is not filled with materials.

16. The electronic device as claimed in claim 1, wherein the pad comprises an under bump metallization (UBM) structure, a bump structure or a pad structure.

17. The electronic device as claimed in claim 1, further comprising an insulation layer disposed between the chip and the second conductive layer, wherein the insulation layer comprises an opening, the chip comprises a chip pad, and the chip pad is disposed in the opening of the insulation layer.

18. The electronic device as claimed in claim 1, wherein the conductive connection layer extends to at least part of surface of the second insulation layer and at least part of surface of the first insulation layer.

19. The electronic device as claimed in claim 1, further comprising a surface mount device (SMD) disposed on the first side of the circuit structure and adjacent to the chip, wherein the surface mount device has a width S, the surface mount device and the chip are separated by a space G, and the space G is greater than or equal to the width S.

20. The electronic device as claimed in claim 1, where a corner edge of the first opening is an arc corner edge, a right angle corner edge or a bevel corner edge.
